(19) United States
(12) Patent Application Publication
(10) Pub. No.: US 2026/0255964 A1
(43) Pub. Date: Aug. 27, 2026

(54) WATER-COOLED HEAT DISSIPATION STRUCTURE CAPABLE OF BEING DESIGNED IN COMPACT SIZE

(71) Applicant: YOUNGYEIL PRECISION CO., LTD., Seoul (KR)

(72) Inventor: Dong Wook CHU, Seoul (KR)

(21) Appl. No.: 19/435,847

(22) Filed: Dec. 30, 2025

(30) Foreign Application Priority Data
Feb. 26, 2025 (KR) 10-2025-0024938

(51) Int. Cl. H10W 40/47; H10W 40/20; H10W 40/22; H10W 40/60; H10W 72/30; H10W 90/00

(52) U.S. Cl. CPC H10W 40/47; H10W 40/226; H10W 40/233; H10W 40/235; H10W 40/242; H10W 40/611; H10W 72/365; H10W 90/736

(57) ABSTRACT

A water-cooled heat dissipation structure capable of being designed in a compact size and also capable of rapidly cooling a semiconductor chip is described. In the water-cooled heat dissipation structure, a first side wall portion and a plurality of fins are formed such that the first side wall portion and the plurality of fins have the same height, so that a space between a heat dissipation plate and a blocking plate is minimized, thereby being capable of designing the entire structure in a compact size.

### CROSS REFERENCE TO RELATED APPLICATION

The present application claims priority to Korean Patent Application No. 10-2025-0024938, filed Feb. 26, 2025, the entire contents of which are incorporated herein for all purposes by this reference.

### BACKGROUND

### Technical Field

The present disclosure relates to a water-cooled heat dissipation structure capable of being designed in a compact size. More particularly, the present disclosure relates to a water-cooled heat dissipation structure capable of cooling a semiconductor chip rapidly and also capable of being designed in a compact size.

### Description of the Related Art

Semiconductor technology has rapidly advanced over the past several decades and has enabled dramatic improvements in the performance of an electronic device. Particularly, a high-density semiconductor chip has become a core component of various electronic devices such as modern computers, smartphones, servers, and so on. However, such a high-density semiconductor chip is experiencing increasingly serious heat generation issues. A device within a semiconductor chip is becoming smaller and is operated faster and, as a result, power consumption of the device has sharply increased and the amount of generated heat has also sharply increased. This heat can not only degrade chip performance but also threaten the long-term reliability and lifespan of the semiconductor chip. Therefore, it is very important to develop effective heat dissipation technology for preventing the overheating of a semiconductor chip.

An air-cooled heat dissipation plate that is a conventional heat dissipation plate is widely used, but the air-cooled heat dissipation plate has a limitation in efficiently dissipating the large amount of heat generated from a high-density semiconductor chip. An air-cooled heat dissipation plate circulates air by using a highly thermally conductive material and a fan and dissipates heat to the outside, but the air-cooled heat dissipation plate has a disadvantage that the air-cooled heat dissipation plate has a large volume and generates noise for sufficiently dissipating heat generated from a high-power chip. In addition, since the thermal conductivity of air is relatively low, the air-cooled heat dissipation plate is insufficient for rapidly transferring the heat of the high-power chip.

In order to solve this problem, a water-cooled heat dissipation plate has gained attention. In a water-cooled heat dissipation plate, heat is absorbed by circulating a refrigerant such as water, and the heat is dissipated to the outside. This system may transfer heat very efficiently by utilizing thermal conductivity characteristics of the refrigerant. In addition, since heat is rapidly dissipated to the outside through the circulation of the refrigerant, the large amount of heat generated from a high-power semiconductor chip may be efficiently dissipated.

FIG. 1 is a view illustrating a conventional water-cooled heat dissipation structure. Referring to FIG. 1, the conventional water-cooled heat dissipation structure includes a heat dissipation plate 10 that is in close contact with a semiconductor chip C, a cover 20 that covers the heat dissipation plate 10, and a refrigerant supply unit 30 configured to supply a refrigerant to a space between the heat dissipation plate 10 and the cover 20. Heat generated from the semiconductor chip is absorbed by the heat dissipation plate, the absorbed heat is transferred through the refrigerant, and the absorbed heat is dissipated to the outside. This method efficiently handles heat, thereby lowering the temperature of the semiconductor chip and increasing the stability of an electronic device.

However, in such a conventional structure, a space is formed between the heat dissipation plate and the cover, so that there is a problem that the space increases the overall volume of the system. Particularly, since a modern electronic device increasingly pursues miniaturization, this increase in size becomes a serious limiting factor. Accordingly, an electronic device that requires high-efficiency heat processing while also needing to be manufactured in a small size face structural constraints, so that there is a problem of resulting in significant difficulties in designing for miniaturization.

### Document of Related Art

(Patent Document 1) Korean Patent No. 10-0805931

### SUMMARY

Accordingly, the present disclosure has been made keeping in mind the above problems occurring in the related art, and an objective of the present disclosure is to provide a water-cooled heat dissipation structure capable of rapidly cooling a semiconductor chip and also capable of being designed in a compact size.

In order to achieve the objective described above, according to an aspect of the present disclosure, there is provided a water-cooled heat dissipation structure capable of being designed in a compact size, the water-cooled heat dissipation structure including: a heat dissipation plate in contact with a semiconductor chip connected to a board; and a blocking plate formed such that the blocking plate covers the heat dissipation plate, the blocking plate having a first side provided with an inlet hole and having a second side provided with an outlet hole, wherein a watertight space portion is formed between the heat dissipation plate and the blocking plate. Furthermore, heat of a refrigerant that is introduced into the space portion through the inlet hole is exchanged with heat of the heat dissipation plate, and then the refrigerant is discharged outside the space portion through the outlet hole.

In addition, the heat dissipation plate may include: a heat dissipation contact portion formed in a plate shape such that the heat dissipation contact portion is in contact with the semiconductor chip; and a first side wall portion that protrudes in a direction opposite to the semiconductor chip along a border of the heat dissipation contact portion, wherein the blocking plate may be formed in a plate shape such that an edge of the blocking plate is in contact with the first side wall portion, and wherein the space portion may be formed in a spaced region between the heat dissipation contact portion and the blocking plate.

In addition, a plurality of fins may be arranged in parallel on an upper surface of the heat dissipation contact portion, wherein the plurality of fins may be formed such that a height of the plurality of fins is same as a height of the first side wall portion or the plurality of fins protrudes upward beyond the first side wall portion, wherein a watertight guide portion may be interposed between the first side wall portion and the edge of the blocking plate such that the plurality of fins and the blocking plate are spaced apart from each other, wherein the space portion may include a channel portion provided between the plurality of fins and a flow space portion provided between an upper end of the plurality of fins and the blocking plate, and wherein the refrigerant introduced into a first side of the flow space portion through the inlet hole may move to the channel portion, may perform heat exchange with the plurality of fins, may move to a second side of the flow space portion, and then may be discharged through the outlet hole.

In addition, a plurality of fins may be arranged in parallel on an upper surface of the heat dissipation contact portion, and the first side wall portion may protrude upward beyond the plurality of fins.

In addition, the semiconductor chip may include a substrate connected to the board, and may include a die mounted on the substrate, wherein the heat dissipation plate may further include a second side wall portion that protrudes downward along the border of the heat dissipation contact portion, wherein the heat dissipation contact portion may be formed such that the heat dissipation contact portion is disposed so as to be in contact with the die and an area of the heat dissipation contact portion is larger than that of the die, so that the die may be disposed in a space between the heat dissipation contact portion and the second side wall portion, and wherein a substrate extension portion may extend from an edge of the substrate such that the substrate extension portion is connected to a lower side of the second side wall portion.

In addition, the lower side of the second side wall portion and the substrate extension portion may be adhered to each other by an adhesive portion.

In addition, a blocking extension portion may extend along the edge of the blocking plate, and a connection portion may be mounted between the blocking extension portion and the board that are facing each other such that the connection portion presses the blocking extension portion toward to the board.

In addition, the connection portion may be formed in a bolt shape, and a plurality of connection portions may be spaced apart from each other along a border of the blocking extension portion.

In addition, the semiconductor chip may include a substrate connected to the board, a die mounted on an upper side of the substrate, and a lid formed such that the lid surrounds a side portion of the die, wherein the heat dissipation plate may be disposed so as to be in contact with the lid, wherein a first thermal conduction portion may be provided between the die and the lid, and wherein a second thermal conduction portion may be provided between the lid and the heat dissipation plate.

In the present disclosure, since the first side wall portion and the fins are formed to have the same height, the space between the heat dissipation plate and the blocking plate is minimized, so that there is an effect that the entire structure is capable of being designed in a compact size.

In addition, since the watertight guide portion is provided between the first side wall portion and the blocking plate, there are effects that the space portion becomes watertight and the fins and the blocking plate are spaced apart from each other.

In addition, since the refrigerant introduced into the flow space portion of the space portion moves to the channel portion and rapidly dissipates heat of the fins, there is an effect that the heat-exchange efficiency is increased. In addition, since the flow space portion promotes the flow of the refrigerant by guiding the inflow and the outflow of the refrigerant, there is an effect that the cooling efficiency is increased.

In addition, since the die of the semiconductor chip is in direct contact with the heat dissipation contact portion, heat generated from the upper side of the die is rapidly transferred to the heat dissipation contact portion and the fins, so that there is an effect that the heat of the die is rapidly dissipated to the refrigerant in the space portion.

In addition, since the second side wall portion is disposed such that the second side wall portion faces a side surface of the die, there is an effect that heat dissipated from the side surface of the die is rapidly dissipated to the outside.

In addition, since the connection portion presses the blocking extension portion toward the board by a screw-fastening manner, the blocking plate and the first side wall portion remain in close contact with each other for a long time even when an external impact is applied, so that there is an effect that the space portion between the blocking plate and the first side wall portion is maintained in a watertight state for a long time.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a conventional water-cooled heat dissipation structure;

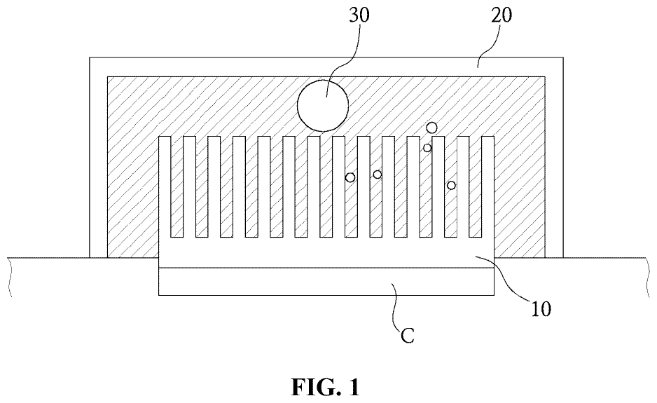

FIG. 2 is a view schematically illustrating a water-cooled heat dissipation structure capable of being designed in a compact size according to an exemplary first embodiment of the present disclosure;

FIG. 3 is a view schematically illustrating the water-cooled heat dissipation structure capable of being designed in the compact size according to an exemplary second embodiment of the present disclosure;

FIG. 4 is a view schematically illustrating the water-cooled heat dissipation structure capable of being designed in the compact size according to an exemplary third embodiment of the present disclosure; and

FIG. 5 is a view schematically illustrating the water-cooled heat dissipation structure capable of being designed in the compact size according to an exemplary fourth embodiment of the present disclosure.

### DETAILED DESCRIPTION

Hereinafter, a water-cooled heat dissipation structure capable of being designed in a compact size according to exemplary embodiments of the present disclosure will be described in more detail with reference to the accompanying drawings.

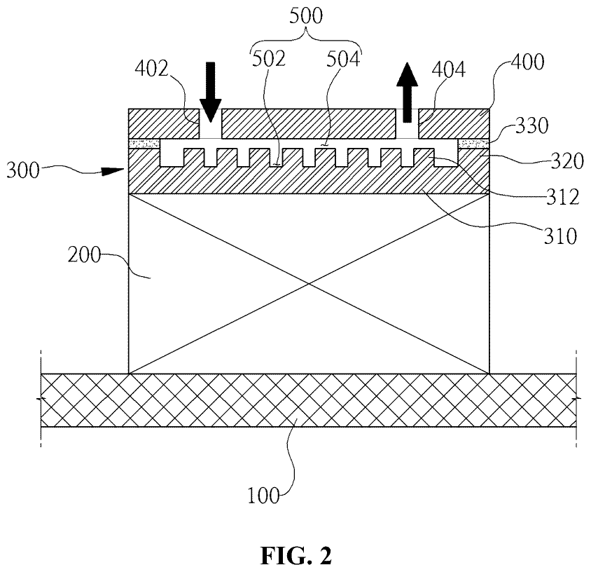

FIG. 2 is a view schematically illustrating a water-cooled heat dissipation structure capable of being designed in a compact size according to an exemplary first embodiment of the present disclosure.

Referring to FIG. 2, the water-cooled heat dissipation structure capable of being designed in a compact size according to the exemplary first embodiment of the present disclosure includes a board 100, a semiconductor chip 200, a heat dissipation plate 300, and a blocking plate 400.

The board 100 includes a main board and so on. The main board is a central circuit board 210 to which various components including the semiconductor chip 200 in a computer or the like are connected and which is configured to transmit various data to each component.

For example, the semiconductor chip 200 includes a Central Processing Unit (CPU) and so on that are core components of a computer, and serves to interpret and execute a command.

The heat dissipation plate 300 is configured to efficiently dissipate heat of the heated semiconductor chip 200 by being in contact with the semiconductor chip 200 that is connected to the board 100, and is configured to prevent overheating of the semiconductor chip 200, thereby preventing performance degradation and damage. The heat dissipation plate 300 includes a heat dissipation contact portion 310 formed in a plate shape so as to be in contact with the semiconductor chip 200, and includes a first side wall portion 320 that protrudes in a direction opposite to the semiconductor chip 200 along a border of the heat dissipation contact portion 310, i.e., the first side wall portion 320 protrudes upward.

A plurality of fins 312 is arranged in parallel on an upper surface of the heat dissipation contact portion 310. The fins 312 have a large surface area and increases a contact area with the refrigerant, thereby effectively dissipating heat generated from the semiconductor chip 200. The heat dissipation contact portion 310, the fins 312, and the first side wall portion 320 are formed integrally with each other, and are formed of a metal material having excellent thermal conductivity.

The blocking plate 400 is formed so as to cover the heat dissipation plate 300, and has an inlet hole 402 formed in a first side of the blocking plate 400 and has an outlet hole 404 formed in a second side of the blocking plate 400. The blocking plate 400 is formed in a plate shape such that edges of the blocking plate 400 are in contact with the first side wall portion 320. A watertight space portion 500 is formed in a space between the heat dissipation contact portion 310 and the blocking plate 400. Heat of a refrigerant introduced into the space portion 500 through the inlet hole 402 is exchanged with heat of the heat dissipation plate 300, and then the refrigerant is discharged to the outside of the space portion 500 through the outlet hole 404. Since the edges of the blocking plate 400 is configured to be in close contact with the first side wall portion 320, the space portion 500 is formed watertightly, so that the refrigerant introduced into the space portion 500 does not leak between the blocking plate 400 and the first side wall portion 320, thereby allowing heat exchange to be smoothly performed.

Meanwhile, the plurality of fins 312 may be formed such that the plurality of fins 312 has a height same as a height of the first side wall portion 320 with respect to the heat dissipation contact portion 310 or protrudes upward beyond the first side wall portion 320. Preferably, the fins 312 and the first side wall portion 320 are formed such that the fins 312 and the first side wall portion 320 have the same height or heights similar to each other. A watertight guide portion 330 formed of a synthetic resin material is interposed between the first side wall portion 320 and the edges of the blocking plate 400 so that the fins 312 and the blocking plate 400 are spaced apart from each other. For example, the watertight guide portion 330 may be formed of epoxy resin or the like. Since epoxy resin has excellent durability and has a strong property of blocking water or other liquids, epoxy resin is advantageous for ensuring watertightness. As such, the watertight guide portion 330 fills a gap between the first side wall portion 320 and the blocking plate 400, and guides the space between the heat dissipation contact portion 310 and the blocking plate 400 to become watertight. In addition, since the fins 312 and the first side wall portion 320 are formed at the same height, the fins 312 and the blocking plate 400 may come into contact with each other. However, in the present disclosure, the fins 312 and the blocking plate 400 are spaced apart from each other by the height of the watertight guide portion 330.

As such, since the first side wall portion 320 and the fins 312 are formed to have the same height, the space between the heat dissipation plate 300 and the blocking plate 400 is minimized, so that there is an effect that the entire structure is capable of being designed in a compact size. In addition, since the watertight guide portion 330 is provided between the first side wall portion 320 and the blocking plate 400, the space portion 500 becomes watertight and, at the same time, the fins 312 and the blocking plate 400 are guided to be spaced apart from each other.

In addition, the space portion 500 includes a channel portion 502 that is a space provided between the plurality of fins 312, and includes a flow space portion 504 that is a space provided between upper ends of the fins 312 and the blocking plate 400. The channel portion 502 and the flow space portion 504 are formed integrally with each other such that the channel portion 502 and the flow space portion 504 are in communication with each other. The refrigerant introduced into a first side of the flow space portion 504 through the inlet hole 402 moves to the channel portion 502, performs heat exchange with the fins 312, moves to a second side of the flow space portion 504, and then is discharged through the outlet hole 404. Here, since the refrigerant guided to the channel portion 502 rapidly dissipates heat of the fins 312, there is an effect that the heat exchange efficiency is increased. In addition, since the flow space portion 504 promotes the flow of the refrigerant by guiding the inflow and the outflow of the refrigerant, there is an effect that the cooling efficiency is increased.

If the fins 312 and the blocking plate 400 come into contact with each other, the refrigerant guided to the channel portion 502 cannot be guided to the outlet hole 404, so that the refrigerant cannot circulate. However, in the present disclosure, since the fins 312 and the blocking plate 400 are spaced apart from each other and the flow space portion 504 is provided between the fins 312 and the blocking plate 400, the refrigerant introduced between the fins 312 and the blocking plate 400 may be easily circulated to the outside.

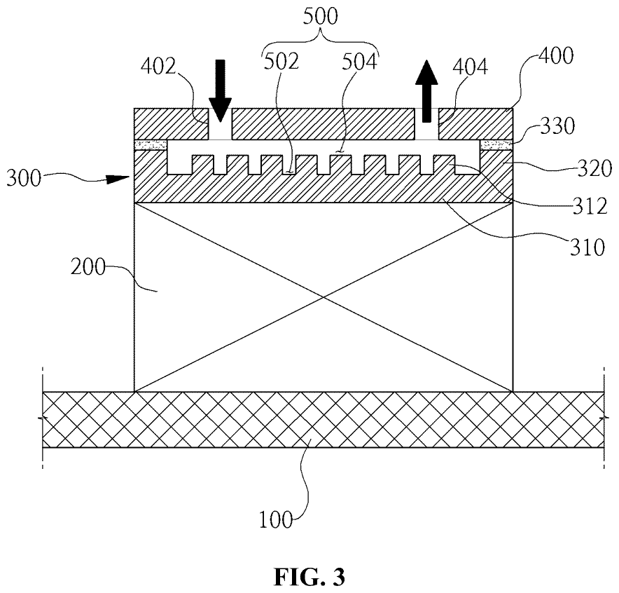

FIG. 3 is a view schematically illustrating the water-cooled heat dissipation structure capable of being designed in the compact size according to an exemplary second embodiment of the present disclosure.

Referring to FIG. 3, the water-cooled heat dissipation structure capable of being designed in the compact size according to the exemplary second embodiment of the present disclosure is the same as the first embodiment, except that the structure of the heat dissipation plate 300 is different. That is, in the second embodiment of the present disclosure, the board 100, the semiconductor chip 200, the heat dissipation plate 300, and the blocking plate 400 are included. The heat dissipation plate 300 includes the heat dissipation contact portion 310, the fins 312, the first side wall portion 320, and the watertight guide portion 330. Here, the first side wall portion 320 protrudes upward beyond the fins 312 with respect to the heat dissipation contact portion 310. As such, the height of the plurality of fins 312 may be freely designed according to a case. When the fins 312 are formed such that the height of the plurality of fins 312 is smaller than the height of the first side wall portion 320, upper sides of the fins 312 are not in contact with the blocking plate 400 even when the height of the watertight guide portion 330 is small, so that the height of the watertight guide portion 330 may be freely designed.

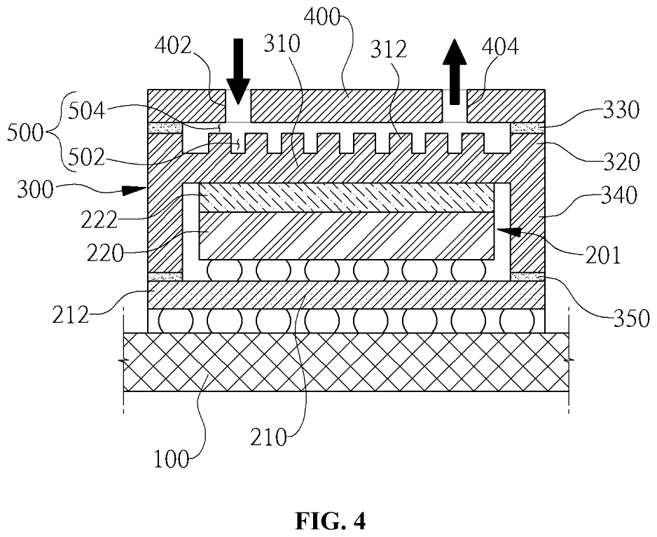

FIG. 4 is a view schematically illustrating the water-cooled heat dissipation structure capable of being designed in the compact size according to an exemplary third embodiment of the present disclosure.

Referring to FIG. 4, the water-cooled heat dissipation structure capable of being designed in the compact size according to the exemplary third embodiment of the present disclosure is the same as the first embodiment, except that the structure of the heat dissipation plate 300 is different. That is, in the third embodiment of the present disclosure, the board 100, a semiconductor chip 201, the heat dissipation plate 300, and the blocking plate 400 are included.

The semiconductor chip 201 includes a substrate 210 connected to the board 100 and a die 220 mounted on an upper side of the substrate 210. The substrate 210 is formed of silicon and so on, and a fine circuit is patterned on the substrate 210. The die 220 is connected to the substrate 210, and the die 220 includes a transistor, a computing unit, a cache memory, and so on. Such a die 220 is a core component of the CPU. In addition, a first thermal conduction portion 222 is provided above the die 220. The first thermal conduction portion 222 is formed of a material having a high thermal conductivity, and may be formed of a Thermal Interface Material (TIM) such as thermal grease, a thermal pad, silicone gel, and so on.

The heat dissipation plate 300 includes the heat dissipation contact portion 310, the fins 312, the first side wall portion 320, and the watertight guide portion 330, and further includes a second side wall portion 340 that protrudes downward along the border of the heat dissipation contact portion 310. In addition, the heat dissipation contact portion 310 is formed such that the heat dissipation contact portion 310 is disposed so as to be in contact with the die 220 and an area of the heat dissipation contact portion 310 is larger than that of the die 220, so that the die 220 is disposed in a space between the heat dissipation contact portion 310 and the second side wall portion 340.

In addition, a substrate extension portion 212 extends from edges of the substrate 210 such that the substrate extension portion 212 is connected to a lower side of the second side wall portion 340, and the lower side of the second side wall portion 340 and the substrate extension portion 212 are adhered to each other by a side wall adhesive portion 350.

As such, since the die 220 is directly in contact with the heat dissipation contact portion 310, heat generated from the upper side of the die 220 is rapidly transferred to the heat dissipation contact portion 310 and the fins 312, so that there is an effect that the heat of the die 220 is rapidly dissipated to the refrigerant in the space portion 500. In addition, since the second side wall portion 340 is positioned such that the second side wall portion 340 faces a side surface of the die 220, there is an effect that heat dissipated from the side surface of the die 220 is rapidly dissipated to the outside.

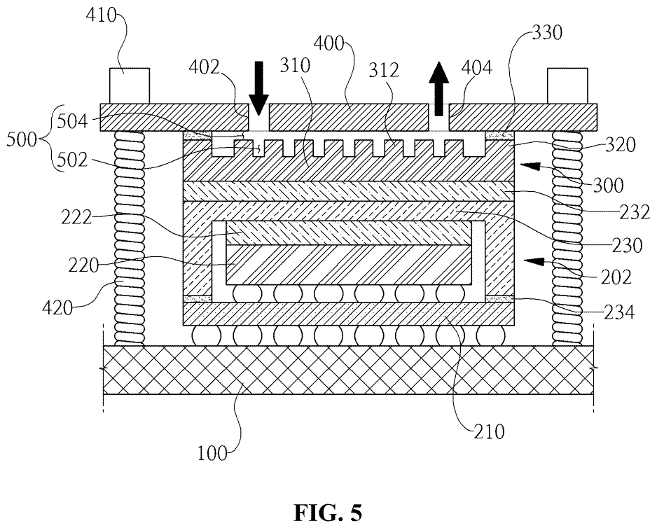

FIG. 5 is a view schematically illustrating the water-cooled heat dissipation structure capable of being designed in the compact size according to an exemplary fourth embodiment of the present disclosure.

Referring to FIG. 5, the water-cooled heat dissipation structure capable of being designed in a compact size according to the exemplary fourth embodiment of the present disclosure is the same as the third embodiment, except that structures of a semiconductor chip 202, the heat dissipation plate 300, and the blocking plate 400 are different. That is, in the fourth embodiment of the present disclosure, the board 100, the semiconductor chip 202, the heat dissipation plate 300, and the blocking plate 400 are included.

In addition to the substrate 210 and the die 220, the semiconductor chip 202 further includes the lid 230. The lid 230 is formed such that the lid 230 convexly protrudes upward so that the lid 230 covers the die 220, is formed of a metal material and so on, and serves to distribute heat generated from the die 220 to the outside and to safely protects the die 220 from the outside. A second thermal conduction portion 232 such as a TIM may be provided between the lid 230 and the heat dissipation plate 300. A lower side of the lid 230 is in contact with the substrate 210. A lid adhesive portion 234 formed of an adhesive material is provided between the lower side of the lid 230 and the substrate 210, so that the lid 230 and the substrate 210 are closely coupled to each other.

In addition, the blocking plate 400 further includes a blocking extension portion 410. The blocking extension portion 410 extends horizontally along the edges of the blocking plate 400 such that the blocking extension portion 410 is positioned outside the first side wall portion 320. In addition, a connection portion 420 is mounted between the blocking extension portion 410 and the board 100 such that the blocking extension part 410 is pressed toward the board 100. For example, such a connection portion 420 is formed in a bolt shape and is disposed between the blocking extension portion 410 and the board 100. Here, a plurality of connection portions 420 is spaced apart from each other at a predetermined distance along the border of the blocking extension portion 410. In addition, the connection portion 420 presses the blocking extension portion 410 toward the board 100 by a screw-fastening method, so that a pressure is equally distributed over the entire border of the blocking plate 400 to the first side wall portion 320. As a result, even when an external impact is applied, the blocking plate 400 and the first side wall portion 320 remain in close contact with each other for a long time, so that the space portion 500 between the blocking plate 400 and the first side wall portion 320 is maintained in a watertight state for a long time.

Although the present disclosure has been described in detail with the above embodiments, the present disclosure is not limited thereto, and it is apparent to those skilled in the art that various changes and modifications may be made within the scope of the technical spirit of the present disclosure, and if these variations and modifications are within the scope of the claims, the technical idea should also be regarded as belonging to the present disclosure.

What is claimed is:

1. A water-cooled heat dissipation structure capable of being designed in a compact size, the water-cooled heat dissipation structure comprising:
a heat dissipation plate in contact with a semiconductor chip connected to a board; and
a blocking plate formed such that the blocking plate covers the heat dissipation plate, the blocking plate having a first side provided with an inlet hole and having a second side provided with an outlet hole,
wherein a watertight space portion is formed between the heat dissipation plate and the blocking plate, and
wherein heat of a refrigerant that is introduced into the space portion through the inlet hole is exchanged with heat of the heat dissipation plate, and then the refrigerant is discharged outside the space portion through the outlet hole.

2. The water-cooled heat dissipation structure of claim 1, wherein the heat dissipation plate comprises:
a heat dissipation contact portion formed in a plate shape such that the heat dissipation contact portion is in contact with the semiconductor chip; and
a first side wall portion that protrudes in a direction opposite to the semiconductor chip along a border of the heat dissipation contact portion,
wherein the blocking plate is formed in a plate shape such that an edge of the blocking plate is in contact with the first side wall portion, and
wherein the space portion is formed in a spaced region between the heat dissipation contact portion and the blocking plate.

3. The water-cooled heat dissipation structure of claim 2, wherein a plurality of fins is arranged in parallel on an upper surface of the heat dissipation contact portion,
wherein the plurality of fins is formed such that a height of the plurality of fins is same as a height of the first side wall portion or the plurality of fins protrudes upward beyond the first side wall portion,
wherein a watertight guide portion is interposed between the first side wall portion and the edge of the blocking plate such that the plurality of fins and the blocking plate are spaced apart from each other,
wherein the space portion comprises a channel portion provided between the plurality of fins, and comprises a flow space portion provided between an upper end of the plurality of fins and the blocking plate, and
wherein the refrigerant introduced into a first side of the flow space portion through the inlet hole moves to the channel portion, performs heat exchange with the plurality of fins, moves to a second side of the flow space portion, and then is discharged through the outlet hole.

4. The water-cooled heat dissipation structure of claim 2, wherein a plurality of fins is arranged in parallel on an upper surface of the heat dissipation contact portion, and the first side wall portion protrudes upward beyond the plurality of fins.

5. The water-cooled heat dissipation structure of claim 2, wherein the semiconductor chip comprises a substrate connected to the board, and comprises a die mounted on the substrate,
wherein the heat dissipation plate further comprises a second side wall portion that protrudes downward along the border of the heat dissipation contact portion,
wherein the heat dissipation contact portion is formed such that the heat dissipation contact portion is disposed so as to be in contact with the die and an area of the heat dissipation contact portion is larger than that of the die, so that the die is disposed in a space between the heat dissipation contact portion and the second side wall portion, and
wherein a substrate extension portion extends from an edge of the substrate such that the substrate extension portion is connected to a lower side of the second side wall portion.

6. The water-cooled heat dissipation structure of claim 5, wherein the lower side of the second side wall portion and the substrate extension portion are adhered to each other by an adhesive portion.

7. The water-cooled heat dissipation structure of claim 2, wherein a blocking extension portion extends along the edge of the blocking plate, and a connection portion is mounted between the blocking extension portion and the board that are facing each other such that the connection portion presses the blocking extension portion toward to the board.

8. The water-cooled heat dissipation structure of claim 7, wherein the connection portion is formed in a bolt shape, and a plurality of connection portions is spaced apart from each other along a border of the blocking extension portion.

9. The water-cooled heat dissipation structure of claim 1, wherein the semiconductor chip comprises a substrate connected to the board, a die mounted on an upper side of the substrate, and a lid formed such that the lid surrounds a side portion of the die,
wherein the heat dissipation plate is disposed so as to be in contact with the lid,
wherein a first thermal conduction portion is provided between the die and the lid, and
wherein a second thermal conduction portion is provided between the lid and the heat dissipation plate.
